(19) United States
(12) Patent Application Publication
(10) Pub. No.: US 2025/0264350 A1
(43) Pub. Date: Aug. 21, 2025

(54) DISPLAY DEVICE, AND METER CONTAINING SUCH A DISPLAY DEVICE

(71) Applicant: Diehl Metering GmbH, Ansbach (DE)

(72) Inventors: Christoph Gronauer, Pyrbaum (DE); Herbert Riegel, Oberdachstetten (DE); Patrick Hünenberger, Ansbach (DE)

(21) Appl. No.: 19/049,210

(22) Filed: Feb. 10, 2025

(30) Foreign Application Priority Data
Feb. 20, 2024 (DE) 10 2024 104 753.4

(51) Int. Cl. G01F 15/14; G01F 15/06

(52) U.S. Cl. CPC G01F 15/14; G01F 15/06

(57) ABSTRACT

A display device contains a carrier plate with one or more electronic components arranged thereon, a carrier for a display, a display arranged on the carrier, and a cover. The cover is transparent at least in a region covering the display. There is formed beneath the cover a sealed cavity in which the display is accommodated. The carrier abuts the cover directly in sealing abutment, and the sealed cavity, in which the display is arranged, is formed between the cover and the carrier. The space that is present outside the cavity between the carrier plate and the cover is filled with a potting compound.

### CROSS-REFERENCE TO RELATED APPLICATION

This application claims the priority, under 35 U.S.C. § 119, of German Patent Application DE 10 2024 104 753.4, filed Feb. 20, 2024; the prior application is herewith incorporated by reference in its entirety.

### FIELD AND BACKGROUND OF THE INVENTION

The invention relates to a display device having a carrier plate with one or more electronic components arranged thereon, a carrier for a display, a display arranged on the carrier, and a cover, which is transparent at least in a region covering the display, wherein there is formed beneath the cover a sealed cavity in which the display is accommodated.

Such a display device serves to display various pieces of information, for example measured values. It is, for example, part of a meter device such as a water meter, electricity meter, gas meter and the like. It may also be part of a manufacturing machine and serve to display operating parameters or other values. Further possible uses are conceivable, the list is not exhaustive.

The display device is usually a separate, prefabricated component, which is connected in a suitable manner both mechanically and electrically to the associated apparatus. It normally has a carrier plate, mostly in the form of a printed circuit board, on which there are arranged one or more electronic components, for example a battery or accumulator, resistors, capacitors, memory chips, processors, etc. There is further provided a carrier, on which there is arranged a display, for example an LCD display, on which the data to be outputted are displayed. The display is arranged beneath a cover, which covers the carrier together with the display, but also the carrier plate together with the component(s). The cover is transparent at least in the region that covers the display, but it may be manufactured entirely from a transparent material, normally plastics material. The display is located beneath and closely adjacent to the cover, or the transparent region, so that it is visible in the best possible manner through the transparent region. A sealed cavity is here formed beneath the cover, or beneath the transparent region, in which cavity the display is accommodated. This is because the rest of the region, or space, between the cover and the carrier plate is normally filled with a potting compound. Because the display device is arranged in the sealed cavity, it is not embedded in the potting compound, that is to say the potting compound cannot penetrate into the region between the cover and the display device, although it can fill the rest of the space. Hitherto, the cavity in which the display device is arranged has been formed by applying to the cover a curing sealant which, when the carrier together with the display is mounted, or the cover is fitted, closes the gap between the carrier and the cover, so that a closed cavity is obtained which is formed on the one hand by the transparent region of the cover and on the other hand by the carrier and the sealant located therebetween. Thus, by means of a suitable application apparatus, a bead of the pasty sealant is applied to the carrier and surrounds the display device completely at the edges. This is complex, since a separate working step is associated with the application, and a corresponding application apparatus has to be provided. Also, the sealant has to cure in order to ensure tightness. If the sealant bead is applied incorrectly, there is the risk that the cavity is not sufficiently sealed and can be penetrated by the potting compound that flows up to the sealant.

### SUMMARY OF THE INVENTION

The invention is based on the problem of providing an improved display device.

With the foregoing and other objects in view there is provided, in accordance with the invention, a display device. The display device contains a carrier plate which has at least one electronic component disposed thereon, a display, a carrier for the display and the display is disposed on the carrier, and a cover being transparent at least in a region covering the display. The carrier abuts the cover directly in a sealing abutment. A sealed cavity is formed beneath the cover and in the sealed cavity the display is accommodated. The sealed cavity is formed between the cover and the carrier. Wherein a space which is present outside the sealed cavity between the carrier plate and the cover is filled with a potting compound.

In order to solve the problem, it is provided according to the invention, in the case of a display device of the type mentioned at the beginning, that the carrier abuts the cover directly in sealing abutment, and the sealed cavity, in which the display is arranged, is formed between the cover and the carrier, wherein the space that is present outside the cavity between the carrier plate and the cover is filled with a potting compound.

In the case of the display device according to the invention, the sealed cavity, in which the display device is accommodated, is formed solely between the cover and the carrier. To this end, the carrier abuts the cover directly in sealing abutment, that is to say there is direct sealing contact between the carrier and the cover. The cavity is closed at the top via the cover and at the bottom via the planar, plate-shaped carrier, which likewise delimits the cavity in the manner of a wall or floor. As a result of the direct sealing contact between the carrier and the cover, sealing between the carrier and the cover is provided solely via the mechanical contact, or the sealing abutment, and an additional sealant, as has hitherto been conventional in the prior art, is therefore not required in the case of the display device according to the invention, which facilitates manufacture. This is because it is simply necessary to bring the carrier, after the carrier has been connected, for example, in a suitable manner to the carrier plate and the display device has been arranged on the carrier, into contact with the cover plate, which takes place automatically, for example, when the cover is fitted over the carrier plate together with the carrier and the display. The seal seat, and thus the sealed cavity in which the display device is accommodated in an encapsulated manner, is formed automatically.

In order to form this sealing abutment, there is provided on the cover in a development of the invention a peripheral abutment region, which the carrier abuts with a likewise peripheral sealing portion. The carrier, which is as it were plate-shaped and preferably rectangular on the side on which the display device is accommodated, thus has at a suitable position a sealing portion which extends around the periphery and is designed for sealing abutment on the cover. The cover likewise has a corresponding peripheral abutment region, which is configured for the sealing abutment of the sealing portion of the carrier. When the cover is joined to the carrier, the sealing portion is automatically brought into contact with the abutment region, whereby the sealing abutment is obtained.

Preferably, the abutment region is here formed by a peripheral cutout, fold or rebate, into which the carrier engages with a shoulder that forms the sealing portion. The sealing portion in the form of the shoulder thus abuts a peripheral wall or an edge of the cutout or fold, whereby the sealing abutment is formed. Positive engagement of the shoulder into the cutout or fold, that is to say of the sealing portion into the abutment region, is preferably provided, so that there is a correspondingly large contact surface between the carrier and the cover, which ensures that sealing abutment is obtained over a large area.

The shoulder preferably engages into the cutout or fold in a positive manner with a press fit. That is to say, the sealing portion is pressed into the abutment region, that is to say the shoulder is received in the cutout or fold in a pretensioned manner and the sealing portion is pressed against the abutment region. To this end, the carrier is configured in the region of the sealing portion with a slight oversize compared to the dimension of the abutment region of the cover. The oversize is, for example, 1/10 mm. Consequently, on joining, the shoulder is pressed into the cutout or fold and the press fit is formed via the oversize, associated with minimal deformation of the sealing portion.

The cutout or fold and/or the carrier can have a sloping surface at least in the region of the sealing portion. This sloping surface, which may also be provided on both sides, permits easier insertion and at the same time ensures a sufficient abutment force for firm positive engagement in the final mounted position.

The carrier itself is preferably made of plastics material, that is to say of a material that has a certain softness, which is expedient for the sealing abutment or the formation of the press fit. The cover is naturally also preferably manufactured from a plastics material, but for reasons of stability from a relatively rigid plastics material. In principle, both the carrier and the cover can be manufactured from any desired plastics materials.

It is conceivable that that carrier has in the sealing portion a coating which is slightly softer than the plastics material forming the carrier. That is to say, the carrier has in the sealing portion an applied plastics soft component, which has been applied in the form of a thin coating and forms the sealing plane, or the direct contact surface, with the abutment region of the cover. The carrier is thus configured in the region of the sealing portion as a 2-component part, wherein the softer plastics material forming the coating can be moulded on or injection-moulded on in a 2K process directly during production of the carrier, which is likewise manufactured from plastics material.

Alternatively or in addition, it is conceivable that the cover also has in the abutment region a coating which is softer than the plastics material of which the cover is formed. Here too, a correspondingly thin coating, which forms the sealing plane and abuts the sealing portion of the carrier, can thus be provided. As described, the cover is normally made of plastics material, for example PMMA, so that, here too, the softer coating can be injection-moulded on in a 2K process directly during production of the cover.

As described, the display is to be connected in a suitable manner to an associated electronic system, via which on the one hand power is supplied, but on the other hand the corresponding signals or data that are to be displayed are also transmitted. To this end, the display device usually has a plurality of contact pins. In order to guide these in a simple manner to the carrier plate and bring them into contact there with conductors or the like, a particularly advantageous development of the invention provides that the carrier has one or more channels through which the contact pins of the display extend. The contact pins, which in most cases project at an angle of 90° from the disc-shaped display, thus extend through the channel(s) and emerge at the end thereof, so that they can be contacted in the region of the emerging ends with the conductors, etc. To this end, the contact pins engage, for example, through through-holes in the carrier plate, in the region of which through-holes actual contact is made. The channels are very narrow, that is to say have a very small cross section, which allows the contact pins to be inserted into and guided through the channel but, at least in some portions, is not much larger than the cross section of the contact pins. This ensures that, although the potting compound can penetrate into such a channel to a certain extent, it cannot penetrate too far into the channel. This is because, as a result of the penetration of the potting compound, a slight excess pressure builds up in the channel, which is necessarily connected to the cavity in which the display is arranged, and prevents further penetration of the potting compound, so that the potting compound can flow in the channel only to a certain level, which, however, is significantly below the plane in which the display device is positioned.

It is expedient for the cross section of the channel(s) to taper to an outlet opening from which the contact pins emerge. Such tapering, for example with an obliquely converging cross section, allows the contact pins, which are threaded from above into the further cross section of the channel(s), to be threaded in more easily and, as a result of the tapering, guided automatically to the outlet opening. The penetration of excess potting compound is already prevented by the outlet opening(s) that is/are only slightly larger in cross section, and further rising in the channel is prevented by the slight excess pressure that develops, as has already been described above.

It can further be provided that a moisture-binding drying agent is accommodated in the cavity. By way of this drying agent, any moisture that is present in the cavity can be bound, for example by adsorption or by chemical means. In order to accommodate the drying agent, the cavity may be made slightly larger if required.

In addition to the display device itself, the invention relates further to a meter, containing a counting device and a display device of the type described above.

The meter is preferably a water meter, that is to say the counting device is configured to record the quantity of water that flows through and optionally further parameters that are relevant in this respect. However, it may also be an electricity meter, a gas meter, a revolution counter or the like.

Other features which are considered as characteristic for the invention are set forth in the appended claims.

Although the invention is illustrated and described herein as embodied in a display device, and a meter containing such a display device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, exploded sectional view of a display device according to the invention;

FIG. 2 is a sectional view of the display device of FIG. 1 in the assembled state; and

FIG. 3 is sectional view of the display device of FIG. 2 after introduction of a potting compound.

### DETAILED DESCRIPTION OF THE INVENTION

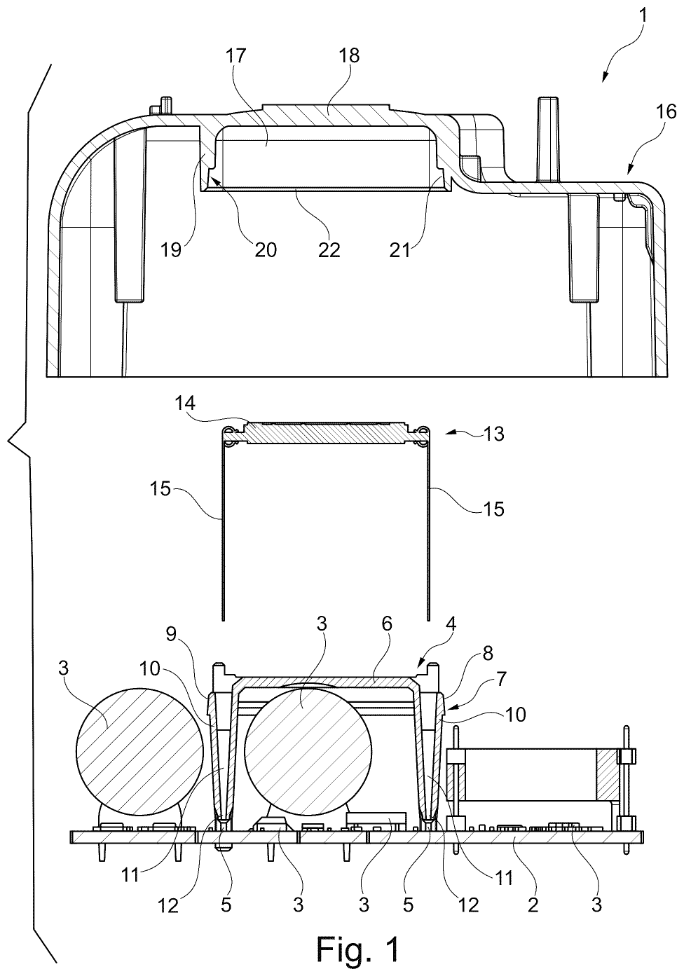

Referring now to the figures of the drawings in detail and first, particularly to FIG. 1 thereof, there is shown an exploded view of a display device 1 according to the invention. The display device has a carrier plate 2, for example a printed circuit board with contact and conductor structures applied thereto. On the carrier plate 2 there are arranged a plurality of electronic components 3, which may be electronic components of any kind, such as batteries or accumulators, capacitors, processors, memories, etc. The electronic components 3 are fastened and contacted in a suitable manner.

There is further arranged on the carrier plate 2 a carrier 4, preferably made of plastics material. The carrier 4 has corresponding fastening portions 5, via which it is fixed to the printed circuit board 2. It further has a plate-shaped holding portion 6, on which a display is arranged in the mounted position.

The carrier 4 has a peripheral sealing portion 7, which is designed to sit in peripheral sealing abutment on a corresponding abutment region of a cover described hereinbelow. The sealing portion 7 is in the form of a peripheral shoulder 8, which extends along all four sides of the rectangular carrier 4. The shoulder 8 has a corresponding sloping surface all the way round, which permits easier insertion and a positive connection to the cover. On two mutually opposite sides of the carrier 4 there are provided channel portions 10 which extend in the direction of the carrier plate 2 and each have one or more channels 11, which serve to receive contact pins which are arranged on the display device, as will be described hereinbelow. The channels 11 taper to the end of the channel portions 10 that is adjacent to the carrier plate 2, where there is provided in each case a corresponding outlet opening 12, which has a significantly smaller cross section compared to the rest of the channel cross section.

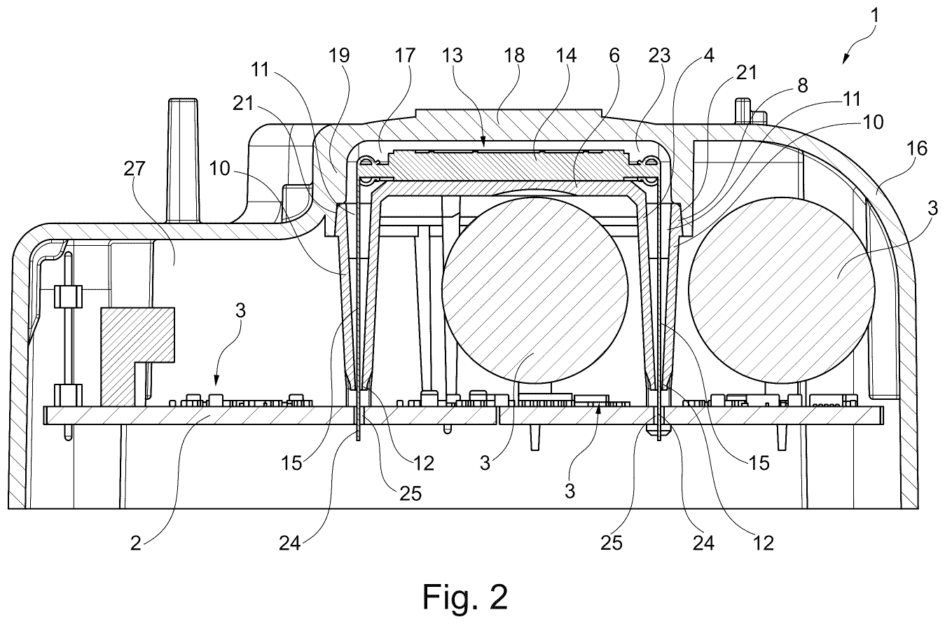

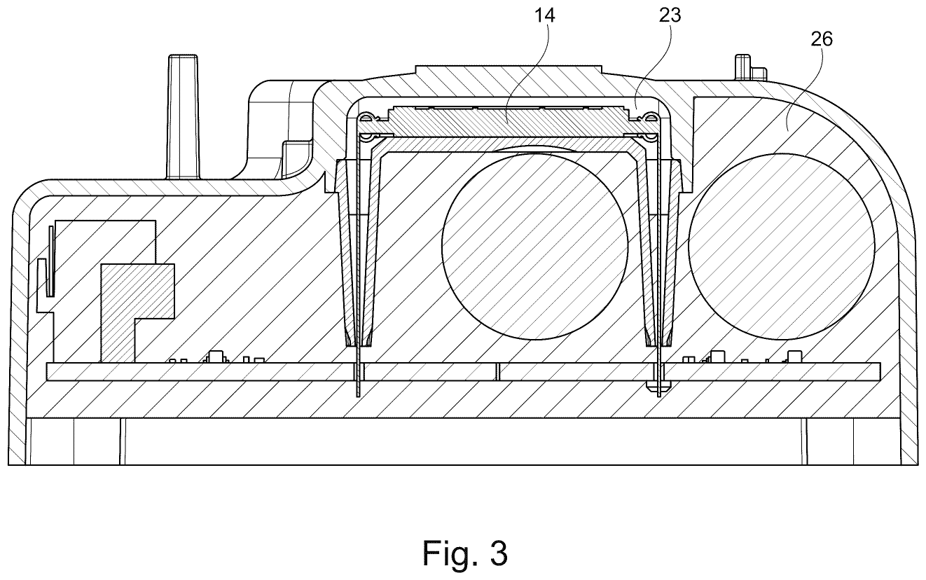

There is further shown a display 13 having the actual display part 14 and a plurality of contact pins 15 provided on both sides of the display. In the mounted position, which will be described hereinbelow in connection with FIGS. 2 and 3, the contact pins 15 have been threaded into the channels 11, and they project with their lower ends out of the outlet openings 12 and engage into corresponding through-holes in the carrier plate 2. At the same time, the display part 14 lies flat on the holding portion 6.

Finally, FIG. 1 shows a cover 16, preferably made of plastics material, such as, for example, PMMA. The cover 16 has an accommodation space 17, which is delimited at the top by a transparent region 18 of the cover 16 and at the sides by a peripheral wall structure 19, which corresponds in cross-sectional shape exactly to the cross-sectional shape of the sealing portion 7, or of the peripheral sealing structure, formed via the shoulder 8, of the carrier 4. The wall structure 19 has a peripheral abutment region 20 in the form of a cutout or fold 21, which likewise has a sloping surface 22 which, in conjunction with the sloping surface 9 of the shoulder 8, permits easier insertion of the shoulder 8 into the cutout or fold 21.

The geometric form and dimensioning of the sealing portion 7, or of the shoulder 8, and of the abutment portion 20, or of the cutout or fold 21, is such that the sealing portion 7, or the shoulder 8, has a slight oversize of approximately 1/10 mm compared to the dimensioning of the abutment portion 20, or of the cutout or fold 21, so that, on joining of the cover 16, the sealing portion 7, or the shoulder 8, is pressed into the abutment region 20, or the cutout or fold 21, that is to say a positive press fit is obtained.

For mounting, the display 13 is first mounted. To this end, the contact pins 15 are threaded into and pushed through the channels 11, wherein they emerge from the outlet openings 12 and, as they move further, are guided through corresponding through-holes in the carrier plate 2, in the region of which contacting takes place. The seating movement is ended when the display part 14 lies on the holding portion 6. The cover 16 is then fitted, wherein the cover 16 is dimensioned such that it also covers the carrier plate 2 at the sides and extends beyond it. During this joining movement, the abutment portion 20, or the cutout or fold 21, is pushed and pressed onto the sealing portion 7, or the shoulder 8, wherein this pushing and pressing on is facilitated by the corresponding sloping surfaces 9, 22, which allow the shoulder 8 to be threaded in a guided manner into the cutout or fold 21. In the final mounted position, the upper edge of the shoulder 8 touches the edge or base of the cutout or fold 21, and at the same time the side surfaces of the shoulder 8 abut and are pressed against the side surfaces of the cutout or fold 21. Overall, the shoulder 8 is thus received in the peripheral cutout or fold 21 with a positive press fit. There is thereby obtained a sealing abutment, that is to say the carrier 4, as a result of this positive press fit, abuts the cover 16 in such a manner that it is sealed completely all the way round. The display 13, or its display part 14, is accommodated in the accommodation space 17 of the cover 16, wherein, as a result of the described sealing abutment, a sealed cavity 23 is formed, in which the display part 14 is accommodated. The cavity 23 is sealed completely with respect to the cover 16, only the channel(s) 11 are open to the outside via their outlet openings 12, since the contact pins 15, as has been described, engage through the channels.

The mounted situation is shown in FIG. 2, which shows a sectional view through the display device 1. There are again shown the carrier plate 2 with the electronic components 3 arranged thereon, and the carrier 4 together with the display 13 arranged thereon. The contact pins 15 have been guided through the channels 11 of the channel portion 10 and emerge to the outside from the outlet openings 12. Their ends 24 engage through corresponding through-holes 25 in the carrier plate 2, where they are contacted. The display part 14 lies on the holding portion 6. The peripheral sealing portion 7, or the peripheral shoulder 8, engages in a positive manner into the peripheral abutment region 20, or the peripheral cutout or fold 21, so that the described press fit and thus the described sealing abutment is obtained. There is formed, as described, the sealed cavity 23, which is delimited at the top by the transparent region 18 and at the sides by the wall structure 19 of the cover, and which is delimited at the bottom by the holding portion 6 and the sealing portion 7. The cavity 23 is open to the outside only via the outlet openings 12, which are very small in cross section.

The display device 1 shown in FIG. 1 is then filled and encapsulated with a potting compound 26. To this end, the arrangement shown in FIG. 3 is rotated, for example, through 180°, so that the carrier plate 2 is at the top and the cover 16 is at the bottom and the fluid potting compound 26 can be introduced from the top. As is shown in FIG. 3, the entire space 27, which is ultimately formed between the cover 16 and the carrier plate 2, is filled with the potting compound 26, apart from the cavity 23 in which the display part 14 is accommodated, which remains unfilled. The initially fluid or pasty potting compound 26 is introduced into the space 27, wherein all the electronic components 3 are embedded completely in the potting compound 26. The potting compound 26 consequently also spreads out beneath the carrier 4, or the receiving portion 6, and fills the space there. As described, the channels 11 are open at the lower end via the outlet openings 12. The fluid potting compound, which has a certain viscosity, can enter the channels 11 via these outlet openings 12. The potting compound can also rise slightly in the channels 11, but the rise is limited. This is because, as has been described, the cavity 23 is sealed. Accordingly, as the potting compound rises further, a slight excess pressure develops in the cavity, since the air contained in the cavity 23 is unable to escape. This is because, on the one hand, there is sealing abutment between the carrier 4 and the cover 16, which prevents air from escaping. And on the other hand, the outlet openings 12 are closed by the potting compound 26 itself. The slight excess pressure accordingly limits the rise height of the potting compound 26 in the channels 11, so that it cannot under any circumstances reach the level of the holding portion 6, or the region of the display part 14. After the potting compound 26 has been introduced, it cures completely, so that on the one hand the entire electronic system is encapsulated completely, as are the carrier and the display, and at the same time the display, or the display part, is located in a cavity that is free of potting compound, so that the display part can be seen unhindered via the transparent region.

A central feature of the display device according to the invention is the direct sealing abutment of the carrier 4 on the cover 16, whereby sealing of the cavity 23 is effected. Consequently, a separate sealant does not have to be applied in this region; instead, sealing is effected directly between the components that are involved via the sealing abutment of the sealing portion 7 on the abutment region 20, or of the peripheral shoulder 8 in the peripheral cutout or fold 21. It is here conceivable that the sealing portion 7 additionally has a coating of a slightly softer plastics material than the plastics material of the carrier, and/or that the abutment region 20 also has such a coating of a slightly softer plastics material than that of the cover 16. Such a very thin coating can be applied or injection-moulded on directly, for example during production of the carrier 4 and/or of the cover 16. By way of this soft coating, the sealing abutment and thus the press fit can be improved still further, if this is necessary at all.

The following is a summary list of reference numerals and the corresponding structure used in the above description of the invention:
1 Display device
2 Carrier plate
3 Electronic component
4 Carrier
5 Fastening portion
6 Holding portion
7 Sealing portion
8 Shoulder
9 Sloping surface
10 Channel portion
11 Channel
12 Outlet opening
13 Display
14 Display part
15 Contact pin
16 Cover
17 Accommodation space
18 Transparent region
19 Wall structure
20 Abutment region
21 Cutout or fold
22 Sloping surface
23 Cavity
24 End
25 Through-hole
26 Potting compound
27 Space

1. A display device, comprising:
a carrier plate having at least one electronic component disposed thereon;
a display;
a carrier for said display, said display disposed on said carrier;
a cover being transparent at least in a region covering said display, said carrier abutting said cover directly in a sealing abutment;
a sealed cavity formed beneath said cover and in said sealed cavity said display is accommodated, said sealed cavity being formed between said cover and said carrier; and
a potting compound, wherein a space being present outside said sealed cavity between said carrier plate and said cover is filled with said potting compound.

2. The display device according to claim 1, wherein:
said carrier has a peripheral sealing portion; and
said cover has a peripheral abutment region which abuts said peripheral sealing portion.

3. The display device according to claim 2, wherein said peripheral abutment region is formed by a peripheral cutout, and into said peripheral cutout said carrier engages with a shoulder that forms part of said peripheral sealing portion.

4. The display device according to claim 3, wherein said shoulder engages into said peripheral cutout in a form-fit manner with a press fit.

5. The display device according to claim 3, wherein said peripheral cutout and/or said carrier has a sloping surface at least in a region of said peripheral sealing portion.

6. The display device according to claim 2, wherein said carrier is made from a plastic material.

7. The display device according to claim 6, wherein said carrier has in said peripheral sealing portion a coating which is softer than said plastic material forming said carrier.

8. The display device according to claim 2, wherein said cover has in said peripheral abutment region a coating which is softer than said plastic material of which said cover is formed.

9. The display device according to claim 1, wherein:
said carrier plate has through-holes formed therein;
said display has contact pins; and
said carrier has at least one channel through which there extend said contact pins of said display which engage through said through-holes in said carrier plate.

10. The display device according to claim 9, wherein said at least one channel has a cross section that tapers to a respective one of said through-holes from which said contact pins emerge.

11. The display device according to claim 1, further comprising a moisture-binding drying agent accommodated in said sealed cavity.

12. A meter, comprising:
a counting device; and
said display device according to claim 1.

13. The meter according to claim 12, wherein the meter is a water meter.
